(19) United States
(12) Patent Application Publication
(10) Pub. No.: US 2025/0318069 A1
(43) Pub. Date: Oct. 9, 2025

(54) Repositional Elements in Network Equipment to Aid Servicing

(71) Applicant: Harmonic, Inc., San Jose, CA (US)

(72) Inventors: Adi Bonen, North York (CA); Eran Schwartz, Kiryat Bialik (IL)

(73) Assignee: Harmonic, Inc., San Jose, CA (US)

(21) Appl. No.: 19/091,385

(22) Filed: Mar. 26, 2025

Related U.S. Application Data
(60) Provisional application No. 63/574,630, filed on Apr. 4, 2024.

(51) Int. Cl. H05K 7/18; H04Q 1/02

(52) U.S. Cl. CPC H05K 7/18; H04Q 1/023

(57) ABSTRACT

A unit of network equipment that comprise at least one repositionable element. The unit of network equipment comprises a modular chassis as well as one or more internal components within its enclosure. Each repositionable element comprises an interface that is shaped to secure in place a line card or a fabric module within the repositionable element. Each repositionable element also comprises a stationary base secured in place and a means for moving the repositionable element between a first position that disposes the interface within the chassis and a second position that disposes the interface beyond a perimeter of the enclosure of the unit of network equipment. The repositionable element may be moved by sliding across one or more elongated rods, by extending one or more telescoping cylinders, using sliding rails, or one or more hinges. The enclosure of the unit of network equipment may conform to a BundesKabelnetz (BK) standard.

### RELATED APPLICATION DATA

The present application claims priority to U.S. Provisional Patent Application No. 63/574,630, entitled ‘In Service Module Extension for Servicing,’ invented by Adi Bonen and Eran Schwartz, filed on Apr. 4, 2024, the entire contents of which are incorporated by reference for all purposes as if fully set forth herein.

### FIELD OF THE INVENTION

Embodiments of the invention relate to equipment having repositionable elements to aid their servicing during operation.

### BACKGROUND

Network equipment, such as cable television nodes, switches, and routers, are often constructed using a modular chassis. The modular chassis is built such that it features cavities or bays of a known form factor to permit various components, such as a line card or a fabric module, to be inserted into the cavity or bay for purposes of securing it in place and allowing the inserted component to interact with the other components housed in the modular chassis. A portion of the module or line card may be exposed to the exterior of the network equipment so that the module or line card may be extracted from the modular chassis to facilitate its service or replacement.

A technician is often required to service network equipment that has been deployed in the field. The technician must have sufficient access to the internal components of the network equipment being serviced, which often requires the technician to access components, such as a line card or a fabric module, that reside within a cavity or bay of the modular chassis of the network equipment. However, designers often have difficulty providing sufficient access to the line card or fabric module due to insufficient free space in front of the line card or fabric module. Components such as a line card or a fabric module often have a large number of connecting wires, cables, fibers, and the like protruding therefrom, which makes it difficult to access the line cards or fabric modules, let alone remove them for servicing. To illustrate the problem, consider FIG. 1A, which is an illustration of a network equipment comprising multiple modules 2 and 4, which may be inserted, installed, or plugged into other pieces of equipment. Modules 2 and 4 each have multiple Ethernet cable connectors 6 to which Ethernet cables are connected. To service line card 4, at a minimum, access to the front of line card 4 is required. A technician in the field attempting to service line card 4 may be required to remove line card 4, but may have limited or impeded access to do so as there may be insufficient accessible area to hold all the parts and/or components that a technician needs access to when servicing line card 4.

In the prior art, this issue has been addressed by (a) increasing the amount of physical space that a line card or fabric module occupies in the chassis in order to provide more physical space dedicated to each line card or fabric module that is accessible for the technician, (b) reducing the usable space for electronic components in the line card or fabric module to improve accessibility, and/or (c) reducing the usable depth of the line cards or the fabric modules to allow for the required bend radius of the protruding wires.

Line cards may themselves have separate pluggable modules attached to their front ports. Non-limiting, illustrative examples of such pluggable modules are pluggable optical interfaces such as SFPs, QSFPs, and XFPs which may be directly inserted into a line card. These pluggable modules often extend beyond the front surface of the line card, and handle fibers that require careful management to ensure that the fibers have a limited bend radius. To ensure that enough space exists for the limited bend radius of those fibers, there must be unoccupied space in front of the line cards for those fibers. The number of pluggable modules that can be attached to a single line card is often limited by the available front area of that line card. In addition, the use of pluggable modules may increase the need for having sufficient physical space in front of a line card, thereby leaving less physical space for the electronic components in the line card itself. However, moving the location to where these pluggable modules are coupled to the line cards to a deeper part within the chassis makes them less accessible to the service technician. This issue particularly presents itself when inserting or extracting the pluggable modules is to be performed when the line card is powered on and in service.

The prior art has often addressed this issue by setting the ports to which pluggable modules or connectors may be attached at an angle. FIG. 1B is an illustration of a line card having tilted ports 6 to which pluggable modules may be connected in accordance with the prior art. The tilted nature of the pluggable modules 6 shown in FIG. 1B reduces the depth in front of the line card for bending fibers. FIG. 1C is an illustration of the depth in front of a chassis required for optical fiber management adhering to allowed fiber bend radius in accordance with the prior art. FIG. 1D is an illustration of a line card with recessed front panel for optical fiber connection that extends less in front of the chassis in accordance with the prior art. As shown in FIG. 1B-D, the reduction of the usable depth of the line cards does allow for the required bend radius of the protruding wires, but at the expense of reducing the available space for the electronic components of the line card. Further, the tight array of protruding wires as shown in FIG. 1C contributes to the difficulties a technician encounters in gaining sufficient access to the line card or fabric module due to insufficient free space in front of the line card or fabric module.

### BRIEF DESCRIPTION OF THE DRAWINGS

Embodiments of the invention are illustrated by way of example, and not by way of limitation, in the figures of the accompanying drawings and in which like reference numerals refer to similar elements and in which:

FIG. 1A is an illustration of a unit of equipment comprising multiple pluggable modules that each have multiple Ethernet cable connections requiring access in front of the unit of equipment and line card typical of the prior art;

FIG. 1B is an illustration of a line card having tilted ports to which pluggable modules may be connected in accordance with the prior art;

FIG. 1C is an illustration of the depth in front of a chassis required for optical fiber management adhering to allowed fiber bend radius in accordance with the prior art;

FIG. 1D is an illustration of a line card with recessed front panel for optical fiber connection that extends less in front of the chassis in accordance with the prior art;

FIG. 2A is a block diagram of an exemplary unit of network equipment having one or more repositionable elements an in accordance with an embodiment of the invention;

FIG. 2B is an illustration of an exemplary unit of network equipment having a repositionable element in accordance with an embodiment of the invention;

FIG. 3A is an illustration of an exemplary repositionable element, disposed in a first position, having elongated rods in accordance with an embodiment of the invention;

FIG. 3B is an illustration of an exemplary repositionable element, disposed in a second position, having elongated rods in accordance with an embodiment of the invention;

FIG. 4A is an illustration of an exemplary repositionable element, disposed in a first position, having one or more telescoping cylinders in accordance with an embodiment of the invention;

FIG. 4B is an illustration of an exemplary repositionable element, disposed in a second position, having one or more telescoping cylinders in accordance with an embodiment of the invention;

FIG. 5A is an illustration of an exemplary repositionable element, disposed in a first position, having sliding rails in accordance with an embodiment of the invention;

FIG. 5B is an illustration of an exemplary repositionable element, disposed in a second position, having sliding rails in accordance with an embodiment of the invention;

FIG. 6A is an illustration of an exemplary repositionable element, disposed in a first position, having one or more hinges in accordance with an embodiment of the invention; and

FIG. 6B is an illustration of an exemplary repositionable element, disposed in a second position, having one or more hinges in accordance with an embodiment of the invention.

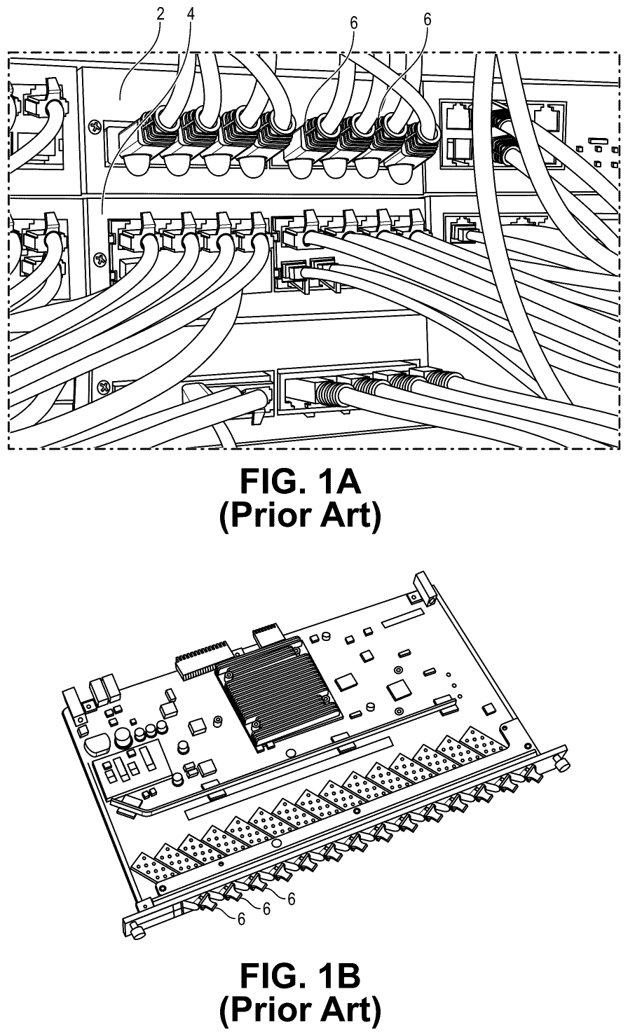

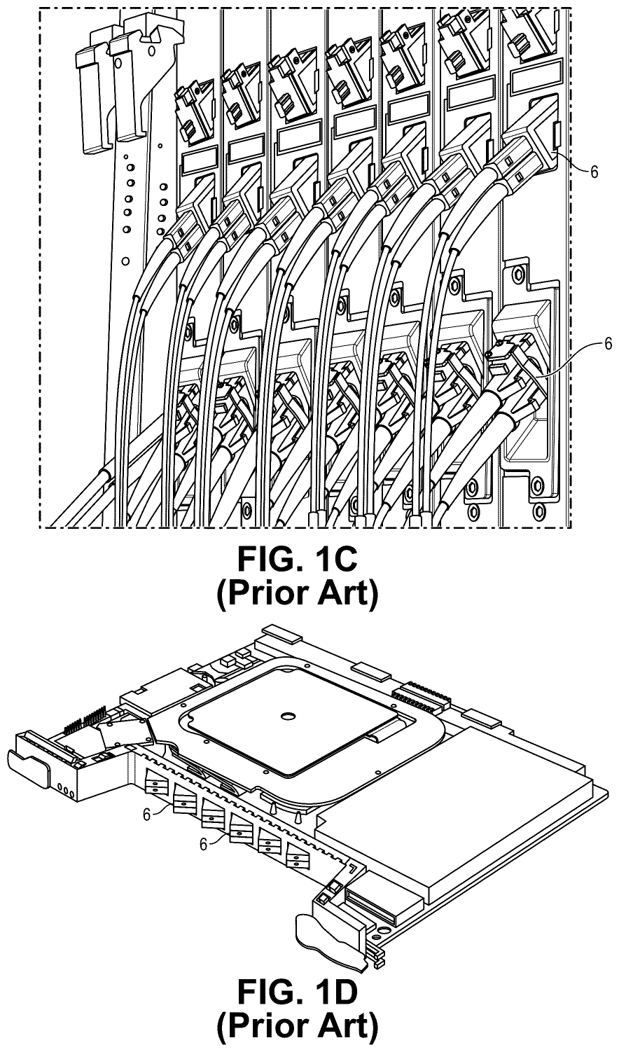

### DETAILED DESCRIPTION OF THE INVENTION

Approaches for a unit of network equipment that comprises at least one repositionable element are presented herein. The following description, for the purposes of explanation, numerous specific details are set forth in order to provide a thorough understanding of the embodiments of the invention described herein. It will be apparent, however, that the embodiments of the invention described herein may be practiced without these specific details. In other instances, well-known structures and devices are shown in block diagram form or discussed at a high level in order to avoid unnecessarily obscuring teachings of embodiments of the invention.

### Functional Overview

Embodiments of the invention advantageously provide for a unit of network equipment to comprise one or more repositionable elements. Such repositionable elements permit a line card, a fabric module, and the like to be manually inserted therein. The repositionable element may be moved to allow a service technician to have greater access to the contents of the repositionable element.

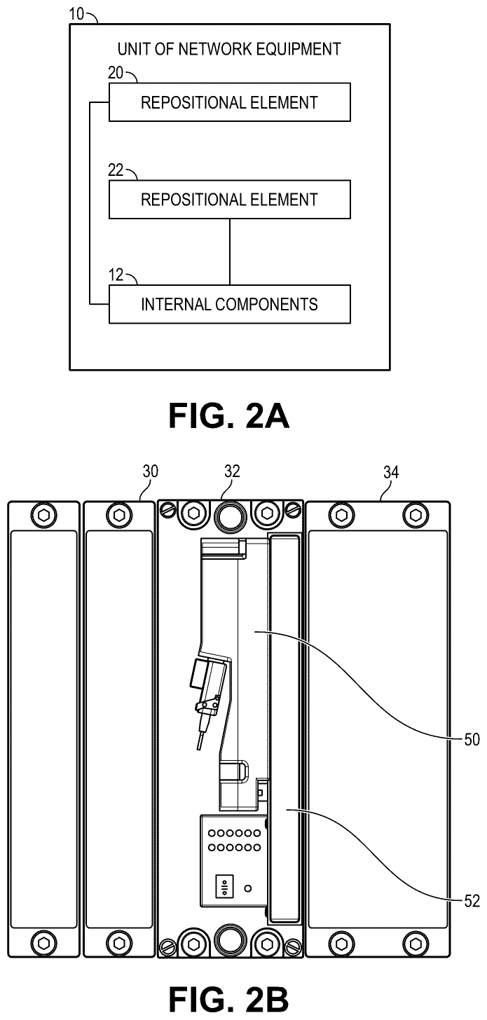

FIG. 2A is a block diagram of an exemplary unit of network equipment having one or more repositionable elements in accordance with an embodiment of the invention. Unit of network equipment 10 represents any type of article of manufacture that may connect to a network. Unit of network equipment 10 may possess a modular chassis that features cavities or bays of a known form factor to permit various components, such as internal components 12 and one or more repositionable elements 20, 22 to be secured thereto. Internal components 12 represents any type of electrical and/or optical components, such as without limitation a printed circuit board (PCB), which performs certain functions of unit of network equipment 10. Internal components 12 may include any number of separate physical components, as this term is broadly used to represent any common element to which each repositionable elements within unit of network equipment 10 may connect.

Unit of network equipment 10 may have an enclosure around the modular chassis that is designed to permit the unit of network equipment 10 to be deployed outdoors or in the elements. To that end, unit of network equipment 10 may be implemented within a hermetically sealed enclosure and operate in a hermetically sealed environment, a vacuum, or orbital environment. In an embodiment, the enclosure of unit of network equipment 10 may correspond to a BundesKabelnetz (BK) standard. Non-limiting, illustrative examples of a unit of network equipment 10 include a wireless communication device, an Ethernet switch, a cable television (CATV) node, an Optical Line Terminal (OLT), a Remote PHY device (RPD), or a Remote MACPHY device (RMD).

During normal operation of unit of network equipment 10, each repositionable element may be collapsed and held within the allocated dimensions of unit of network equipment 10. To illustrate, consider FIG. 2B, which is an illustration of an exemplary unit of network equipment having a repositionable element 32 in accordance with an embodiment of the invention. As shown in FIG. 2B, repositionable element 32 is adjacent on both sides to components 30 and 34. Components 30 and 34 may be line card and/or fabric modules as existing in the prior art. Repositionable element 32 comprise interface 52, which is a physical component that is shaped to secure in place a line card or fabric module 50 within repositionable element 32. Interface 52 can be constructed to have circuitry that provides a communication channel, such as but not limited to an electrical or optical pathway, between internal components 12 and line card or fabric module 50.

As can be appreciated from viewing FIG. 2B, components 30 and 34, and their producing wires and/or pluggable modules inhibit access to repositionable element 32 and the line card or fabric module 50 comprised therein. Advantageously, during maintenance repositionable element 32 may be extended from its normal position during operation towards the space in front of the chassis so that a service technician may be provided access to the sides of repositionable element 32, which are normally blocked by other modules inserted in the chassis adjacent to repositionable element 32, as shown in FIG. 2B.

### Repositionable Element to Facilitate Service

Unit of network equipment 10 may comprise any number of repositionable elements. Each repositionable element comprises a means for moving the repositionable element over a range of positions between a first position and a second position. The first position is the position during normal operation of the unit of network equipment 10, in which the interface of the repositionable element is disposed within the chassis. The second position is the position in which a service technician may gain access to the interior components of the repositionable element, in which the interface is disposed beyond a perimeter of the enclosure of the unit of network equipment 10.

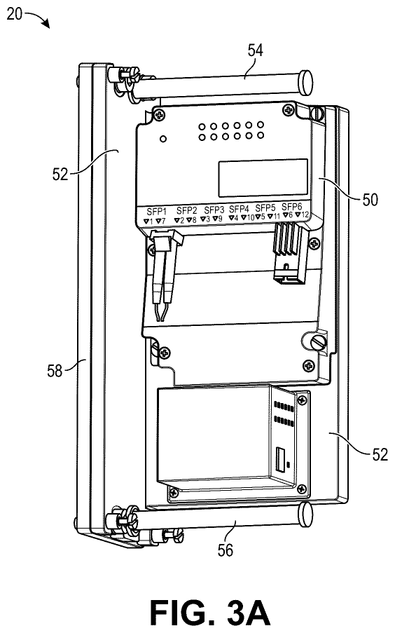

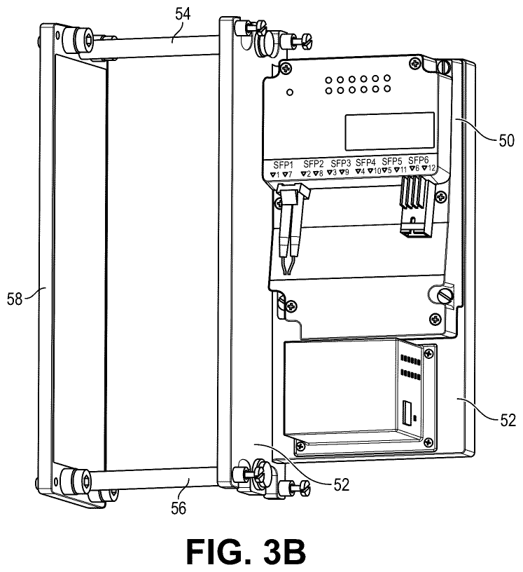

Embodiments may use a variety of different means for moving the repositionable element over a range of positions. To illustrate, consider FIG. 3A, which is an illustration of an exemplary repositionable element 20, disposed in the first position, which has elongated rods 54, 56 in accordance with an embodiment of the invention. Similarly, FIG. 3B is an illustration of an exemplary repositionable element 20, disposed in the second position, which has elongated rods 54, 56 in accordance with an embodiment of the invention. FIGS. 3A and 3B both depict interface 52, which is shaped to secure in place a line card a fabric module within repositionable element 20. Interface 52 may embody or make use of a generic extension mechanism that supports multiple types of modules, devices, or cards to be secured to interface 52 for purposes of establishing a communication channel between any module, device, or card secured thereto and the internal components 12 of unit of network equipment 10. In the examples of FIGS. 3A-6B, line card 50 is shown secured to interface 52.

FIGS. 3A and 3B both depict stationary base 58, which may be secured in place to unit of network equipment 10, e.g., stationary base 58 may be secured in place to the chassis. First elongated rod 54, secured to stationary base 58, extends through a first hole in interface 52. Similarly, second elongated rod 56, secured to stationary base 58, extends through a second hole in interface 52. As shown in FIGS. 3A and 3B, first elongated rod 54 and second elongated rod 56 are on opposing sides of interface 52. The first and second holes in interface 52 are sized to permit interface 52 to slide along elongated rods 54, 56 between the first position shown in FIG. 3A and the second position shown in FIG. 3B.

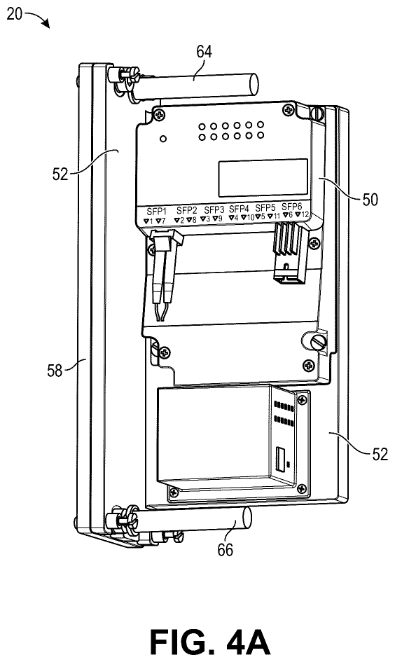

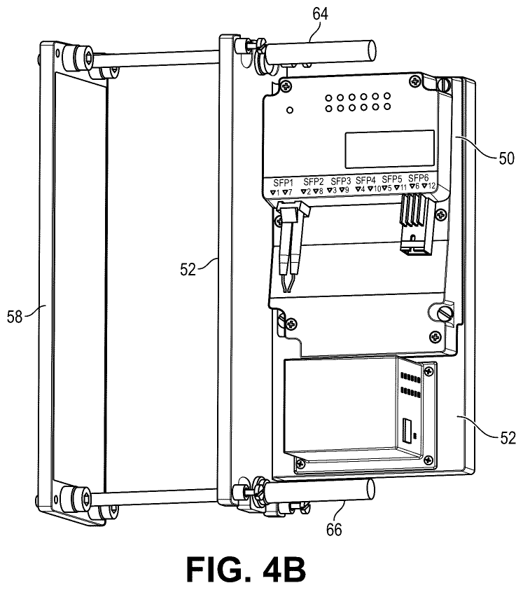

Another exemplary embodiment is depicted in FIGS. 4A and 4B, which depict exemplary repositionable element, disposed in first and second positions respectively, having one or more telescoping cylinders in accordance with an embodiment of the invention. As shown in FIGS. 4A and 4B, first telescoping cylinder 64 is secured to a first side of stationary base 58 and to a first side of interface 52, while second telescoping cylinder 66 is secured to a second side of stationary base 58 and to a second side of interface 52. In FIGS. 4A and 4B, first telescoping cylinder 64 and second telescoping cylinder 66 are on either side of interface 52, although that need not necessary be the case in every embodiment. Telescoping cylinders 64 and 66 permit interface 52 to move over a range of positions by their extension and compaction.

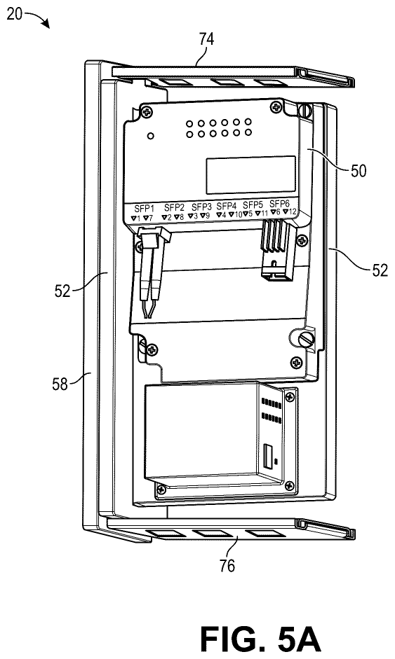

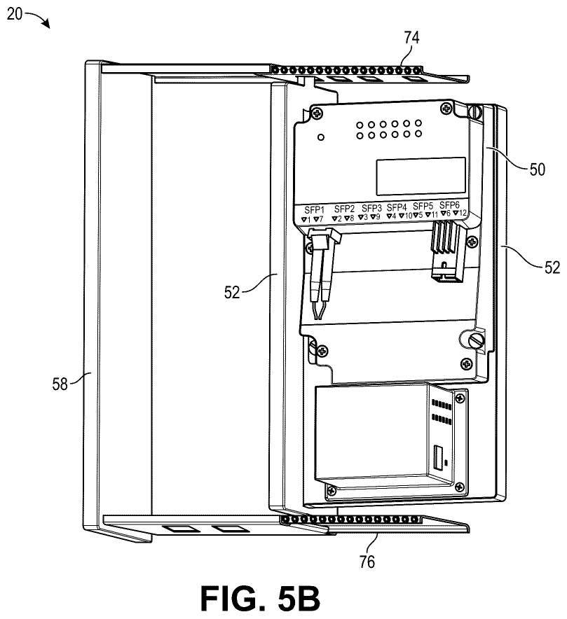

FIGS. 5A and 5B depict another exemplary repositionable element having sliding rails in accordance with an embodiment of the invention. FIG. 5A depicts the repositionable element having sliding rails in the first position, while FIG. 5B depicts the repositionable element having sliding rails in the second position. A first set of sliding rails 74 are secured to a first side of stationary base 58 and to a first side of interface 52, while a second set of sliding rails 76 secured to a second side of stationary base 58 and to a second, opposing side of interface 52. The sliding rails operate akin to a drawer-like slide to permit interface 52 to move over a range of positions.

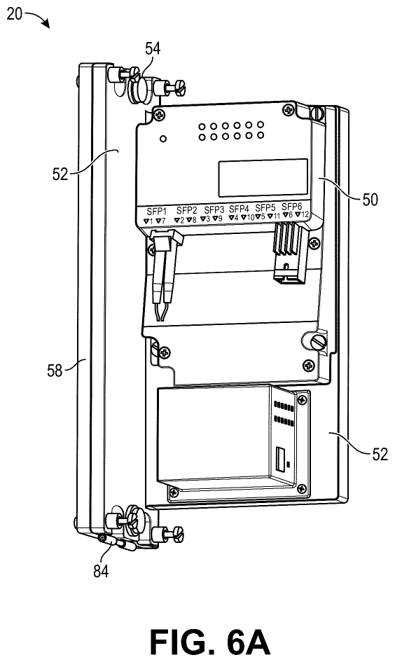

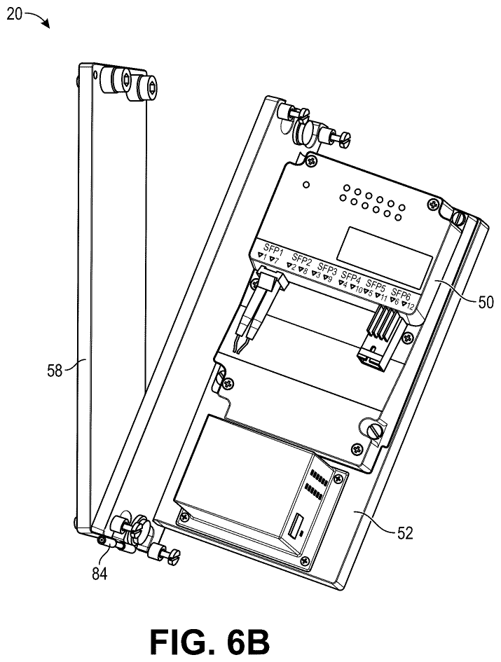

Another exemplary embodiment is depicted in FIGS. 6A and 6B, which depict an exemplary repositionable element, disposed in first and second positions respectively, having one or more hinges in accordance with an embodiment of the invention. As shown in FIGS. 6A and 6B, interface 52 is rotatably secured to stationary base 58 by one or more hinges 84 to permit interface 52 to rotate around an axis created by one or more hinges 84 to move between the first position and the second position.

In an embodiment, when a repositionable element is in the first position, i.e., the non-extended position, the repositionable element may be fastened such that it will remain in place and not be accidentally moved, rotated, or extended. In embodiments of the invention, a repositionable element may be secured to remain in place in the second position, i.e., the fully extended state, such that the repositionable element is positioned solidly and can be mechanically handled by the service technician without accidently movement, rotation, or extension. In embodiments of the invention, a repositionable element may be secured to remain in place in a partially extended state such that the repositionable element is positioned solidly and can be mechanically handled by the service technician without accidently movement, rotation, or extension.

In an embodiment, when interface 52 is disposed in the first position, interface 52 makes physical contact with a thermal conductor that extends through stationary base 58 to make physical conduct with the enclosure of unit of network equipment 10. In this way, heat generated by interface 52, or any line card or fabric module plugged into interface 52, may be conducted via the thermal conductor to the exterior of the enclosure of the unit of network equipment. Other embodiments may conduct heat away from interface using a thermal conductor to other areas within unit of network equipment 10 which are less susceptible to overheating that the general area of interface 52 and/or anything plugged therein. Non-limiting, illustrative examples of the thermal conductor include the thermal conductive pedestals disclosed in U.S. patent application Ser. No. 18/266,602 for Cooling of Pluggable Devices in Device Ports Using Thermal Conductive Pedestals, invented by Adi Bonen et al., filed Jul. 26, 2023, the entire disclosure of which is hereby incorporated by reference for all purposes as if fully set forth herein.

Some embodiments may also use thermal conductance to move heat away from any device plugged into interface 52, such as a line card or fabric module, without using a separate thermal conductor. In such an embodiment, interface 52 itself may operate as a thermal conductor that enables heat to be transferred away from a device plugged into interface 52 to another area less susceptible to overheating that the general area of interface 52 and/or anything plugged therein. In doing so, interface 52 may transfer heat to one or more other physical components that are designed to aid in the transfer of heat or act as a heat sink.

In an embodiment, interface 52 is designed and constructed with sufficient thermal mass to prevent rapid temperature rise at any line card or fabric module plugged into interface 52. In this way, when interface 52 is disposed in the second position, temperature rise due to heat generated by a component plugged into interface 52 can be held to sufficiently lower value to enable a technician to conclude a required maintenance and return interface 52 to the first position in which better cooling is provided.

### Deployment Alternatives

While embodiments of the invention have chiefly been described in term of network equipment, other embodiments of the invention may be employed with other types of equipment, such as television sets, personal computers, computer monitors, audio equipment, and the like. In such embodiments, repositionable elements may comprise an interface that is shaped to secure in place certain types of cables appropriate for that equipment within the repositionable element. In this way, the interface may allow one to either plug a cable having a certain form factor into a television set, personal computer, computer monitor, or audio equipment using a repositionable element as described herein.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A unit of network equipment, comprising:
a modular chassis;
one or more internal components within an enclosure of the unit of network equipment; and
at least one repositionable element, each repositionable element comprising:
an interface that is shaped to secure in place a line card or a fabric module within the repositionable element,
a stationary base secured in place to said unit of network equipment,
means for moving said repositionable element between a first position and a second position,
wherein said first position disposes said interface within said chassis, and
wherein said second position disposes said interface beyond a perimeter of the enclosure of said unit of network equipment.

2. The unit of network equipment of claim 1, wherein said line card comprises a plurality of device ports, wherein one or more of said plurality of device ports is coupled to one or more of a small form-factor pluggable device (SFP), an XFP optical transceiver, an SFP+optical transceiver, a Quad Small Form-factor pluggable plus (QSFP+) device, and a CF2 device.

3. The unit of network equipment of claim 1, wherein said unit of network equipment is a wireless communication device, an Ethernet switch, a cable television (CATV) node, an Optical Line Terminal (OLT), a Remote PHY device (RPD), or a Remote MACPHY device (RMD).

4. The unit of network equipment of claim 1, wherein said unit of network equipment is disposed in a hermetically sealed environment, a vacuum, or orbital environment.

5. The unit of network equipment of claim 1, wherein said enclosure of said unit of network equipment conforms to a BundesKabelnetz (BK) standard.

6. The unit of network equipment of claim 1, wherein said each repositionable element further comprises a means for preventing the interface from leaving the first position without manual intervention.

7. The unit of network equipment of claim 1, wherein said means for moving said repositionable element between said first position and said second position comprises:
a first elongated rod secured to said stationary base and extending through a first hole in said interface, and
a second elongated rod secured to said stationary base and extending through a second hole in said interface, wherein said first elongated rod and said second elongated rod are on either side of said interface, and
wherein said first and second holes are sized to permit said interface to slide along said first and second elongated rods between said first position and said second position.

8. The unit of network equipment of claim 1, wherein said means for moving said repositionable element between said first position and said second position comprises:
a first telescoping cylinder secured to a first side of said stationary base and a first side of said interface, and
a second telescoping cylinder secured to a second side of said stationary base and a second side of said interface, wherein said first telescoping cylinder and said second telescoping cylinder are on either side of said interface, and
wherein said first telescoping cylinder and first telescoping cylinder permit said interface to move over a range of positions by extension and compaction of said first telescoping cylinder and said second telescoping cylinder.

9. The unit of network equipment of claim 1, wherein said means for moving said repositionable element between said first position and said second position comprises:
a first set of sliding rails secured to a first side of said stationary base and a first side of said interface, and
a second set of sliding rails secured to a second side of said stationary base and a second side of said interface, wherein said first telescoping cylinder and said second telescoping cylinder are on either side of said interface, and
wherein said first and second sets of sliding rails permit said interface to over a range of positions.

10. The unit of network equipment of claim 1, wherein said means for moving said repositionable element between said first position and said second position comprises:
one or more hinges that rotatably secure said interface to said stationary base to permit the interface to rotate around an axis created by said one or more hinges.

11. The unit of network equipment of claim 1, wherein said interface provides a communication channel between said one or more internal components and any line card or any fabric module secured to said interface.

12. The unit of network equipment of claim 1, wherein said first position disposes a thermal conductor in contact with said interface, wherein said thermal conductor extends through said stationary base to make physical conduct with said enclosure of said unit of network equipment.

13. The unit of network equipment of claim 1, wherein said interface is a thermal conductor capable of facilitating a transfer of heat away from any pluggable device secured by said interface.

14. The unit of network equipment of claim 1, wherein said interface, when disposed in said second position, possesses sufficient thermal mass to prevent rapid temperature rise in adjacent physical components.
